(19) United States
(12) Patent Application Publication
(10) Pub. No.: US 2004/0090291 A1
(43) Pub. Date: May 13, 2004

(54) Method and apparatus for refurbishing analog set top box to provide digital set top box and optional DOCSIS cable modem capability

(76) Inventors: Selim Shlomo Rakib, Cupertino, CA (US); James David Watkins, San Jose, CA (US)

Correspondence Address: RONALD CRAIG FISH, RONALD CRAIG FISH, A LAW CORPORATION, POST OFFICE BOX 2258, MORGAN HILL, CA, 95038, US

(21) Appl. No.: 10/294,672

(22) Filed: Nov. 13, 2002

(51) Int. Cl. H03J 5/00; H05K 3/20; H05K 3/30

(52) U.S. Cl. 334/1; 29/832; 29/831; D14/265; D14/188

(57) ABSTRACT

A process for refurbishing analog set top tuner/decoders which are not compatible with digital cable to convert same into a digital set top tuner/decoder which can tune any channel on a digital cable system and convert the digital data received on that channel into a video signal. The process comprises forming a replacement circuit and mounting said replacement circuit on the motherboard of the target set top tuner/decoder and then making circuit breaks at the appropriate points on the motherboard of said target set top tuner/decoder and connecting the appropriate points on the replacement circuit to the appropriate circuit breaks to complete the conversion.

### BACKGROUND OF THE INVENTION

There are currently a vast number of analog set top boxes that cable system operators have deployed. These set top boxes are used to couple the hybrid fiber coaxial cable system to the subscriber's television set. The old way to deliver cable TV content was analog with one TV signal per 6 MHz channel. The new way to deliver TV programs is digital with multiple programs delivered in compressed MPEG transport streams such that 10-12 programs can be delivered digitally over a single 6 MHz channel. This frees up a large amount of bandwidth, and allows cable operators to provide more regularly scheduled programs in addition to many pay per view channels and many video on demand channels. MPEG compression compresses a raw digital representation of a television program down to between 2.5 and 3.5 megabits per second. DOCSIS 2.0 QAM 64 and QAM 128 modulation bursts with 512 megasymbols per second symbol rate provide 38 megabits per second throughput per channel and occupy 6 MHz of bandwidth. Thus 10-12 video channels can be transmitted on a single DOCSIS 2.0 512 megasymbol per second QAM 128 channel.

Existing analog set top boxes only allow the user to flip between different channels. They do not have facilities to provide display of digital data which displays the program schedule or information about particular programs such as the actors and plot synopsis.

It is therefore, very advantageous to deploy digital set top boxes to replace analog set top boxes in the homes of subscribers. However, because the cable operators already have a substantial amount of capital invested in the deployed analog set top boxes, a need has arisen for a way to refurbish those analog set top boxes to make them compatible with digital cable delivery of video and broadband services via DOCSIS 2.0, 1.1 or 1.0 digital services.

### SUMMARY OF THE INVENTION

The genus of processes within the teachings of the invention is characterized by the shared characteristics of: creating a replacement circuit which has the capability to be connected to certain components of an analog set top box that can be re-used to make the combination into a digital set top box; mounting the replacement circuit on a printed circuit board and making connection pads for the replacement circuit; and making breaks in the conductive traces of the motherboard of the analog set top box at predetermined locations; and making suitable connections between the connection pads of the replacement circuit and the appropriate points on the breaks in the circuit traces of the motherboard to form a digital set top tuner/decoder which re-uses certain components of the analog set top box.

### BRIEF DESCRIPTION OF THE DRAWINGS

FIG. 1 is a block diagram of a typical analog set top decoder box.

FIG. 2 is a block diagram of a typical replacement circuit to make an analog set top box into a digital set top box.

FIG. 3 is a diagram of a typical mounting and connection of a replacement circuit board.

### DETAILED DESCRIPTION OF THE PREFERRED AND ALTERNATIVE EMBODIMENTS

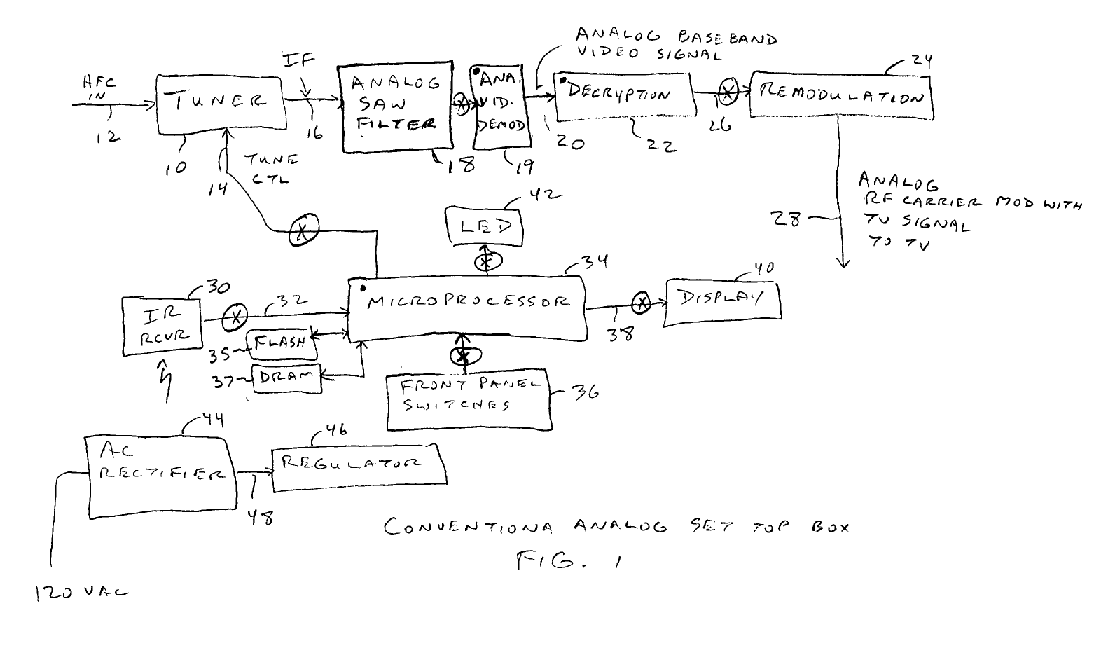

FIG. 1 is a block diagram of a typical analog set top decoder box. An RF tuner 10 receives a whole spectrum of radio frequency CATV signals at different frequencies from hybrid fiber coaxial cable system 12, each bearing a different program. A tuning signal on line 14 controls which channel the tuner selects. The resulting selected channel is mixed down to an intermediate frequency on line 16 which is at the center frequency of an analog SAW filter 18. The output of the SAW filter is demodulated in an analog video demodulator 19. The SAW filter is a passband filter with sharp rolloff skirts. It filters out noise outside the selected channel. The filtered analog IF signal is then demodulated in the demodulation section, and a baseband analog video signal is output on line 20 to a decryption circuit 22. The decryption circuit unscrambles the analog video signal, and makes sure it does not get through if the user does not have an authentic decryption key. A remodulation circuit 24 then remodulates the decrypted baseband video signal on line 26 onto an radio frequency carrier having the frequency of channel 3 or channel 4 of the tuner of a television set coupled to output coax 28.

An infrared receiver 30 receives infrared commands from a remote control to change channels and converts these infrared signals to electrical signals on line 32. Microprocessor 34 receives these signals on line 32, and possibly receives other signals from front panel switches 36 if front panel switches are present, and converts commands to change channels to a tuning command on line 14. The microprocessor also displays the current channel via signals on line 38 to segment display 40. The microprocessor has flash memory 35 and DRAM 37 to store its program and data, respectively.

The microprocessor 34 may also indicate the status of the unit through LEDs 42. The set top box also includes an AC rectifier 44 to convert 120 volts AC wall power to DC voltages needed by the circuitry in the set top box. A regulator 46 smoothes out the DC output and regulates the voltage thereof and may generate several different DC voltages from a single DC voltage input on line 48.

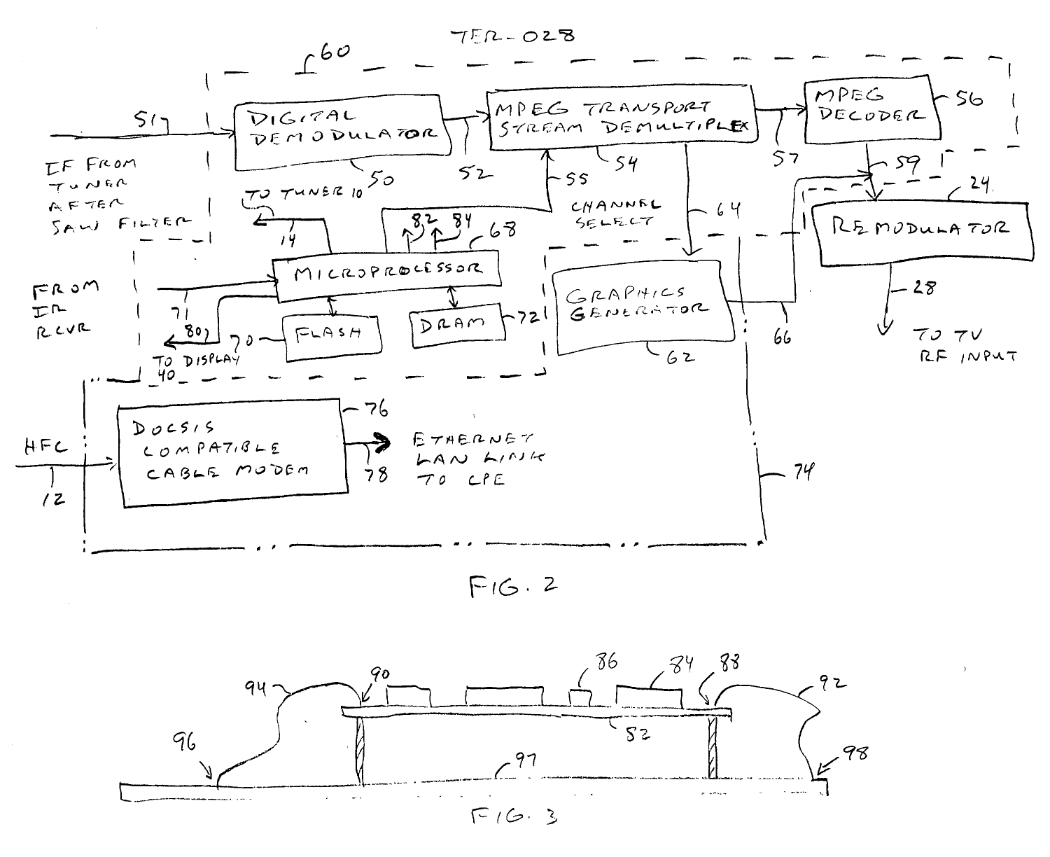

Referring to FIG. 2, there is shown the circuitry needed to convert the analog set top box of FIG. 1 to a digital set top box. The intermediate frequency signal on line 51 from the tuner 10 in FIG. 1, after filtering by the SAW filter 18, is demodulated by a known digital video demodulator circuit 50. A baseband signal MPEG transport stream in a digital representation is output on line 52 to an MPEG transport stream demultiplexer 54. In digital video and DOCSIS downstreams, video programs the various broadband services are encoded into MPEG packets, and each different service has a different code called a PID or program identifying information in the packet headers so that the different packets can be sorted into the different programs and kept together. This is done by the transport stream demultiplexer 54 which is a known circuit from existing digital set top boxes. A channel select signal on line 55 controls the transport stream demultiplexer and tells it which particular program in the MPEG transport stream whose packets are to be culled out. The culled packets are output line 57.

A known MPEG decoder 56 decodes the MPEG packets on line 57 belonging to the selected MPEG stream and converts the compressed MPEG data therein to a baseband analog video signal on line 59. In some embodiment, the baseband video signal may be output in parallel at baseband video and audio output jacks of the commonly used RCA variety or at an S-video output jack. In some embodiments, this is the only output of the video signal. In most embodiments however, for backward compatibility with TVs that do not have baseband video inputs, the analog video signal on line 59 is coupled to the input of the remodulator 24 from the original set top decoder box which modulates the baseband video signal onto an RF carrier on line 28 at the frequency of channel 3 or 4 for input to the RF input of a television set.

A known graphics generator 62 receives digital supplementary data from the transport stream demultiplexer on line 64. This supplementary data includes data such as the name of the program, the time it starts and finishes, the actors and a plot summary or any other auxiliary data useful to the user. This data is converted into graphics video signals on line 66 and fed to the input of the remodulator for display on the television.

A microprocessor 68 receives channel selection commands from the IR receiver via line 71 and, under the control of a program stored in flash EEPROM 70, it generates suitable channel select commands on line 55 for the MPEG transport multiplexer circuit 54 to cause the desired packets to be culled out of the MPEG transport stream and generates a tuner control signal on line 14 to control tuner 10 in FIG. 1. The microprocessor is coupled to DRAM 72 to store data. The microprocessor 68 is also coupled by bus 80 to the display 40 in FIG. 1, and is coupled to LEDs 42 by line 82. Microprocessor 68 can also be used to authenticate users and may be coupled to an access card reader (not shown). In alternative embodiments, a separate authentication circuit of a type known to digital set top boxes (not shown) is included in the circuitry of FIG. 2 at a suitable point. The microprocessor 68 is also coupled by line 84 to the front panel switches. The word “line” as it is used herein denotes as many separate conductors as are necessary to communicate appropriate signals with the particular device to which the line is coupled.

The circuitry shown in FIG. 2 inside dashed line 60 is all that is necessary to emulate the channel picking functionality of the analog set top box for a digital video delivery HFC system 12. The circuitry inside dashed line 60 replaces the circuitry in FIG. 1 with dots in the upper left hand corners and all the other circuitry is re-used. In some embodiments where the flash memory 35 and DRAM 37 in FIG. 1 are big enough to serve for the digital circuitry of FIG. 2, they are re-used, but in other embodiments, they are replaced by flash 70 and DRAM 72 in FIG. 2.

In more complex embodiments, where the user wants the convenience of graphics with program information and other broadband services that can be sent over a DOCSIS downstream, the circuitry inside dash-dot-dot line 74 is added to the replacement circuitry. The added circuitry is the graphics generator 62 and any known DOCSIS compatible cable modem 76. The cable modem is coupled to the HFC system 12 and outputs DOCSIS data on a local area network link 78 which is coupled to customer premises equipment such as computers, digital phones and FAXes and any other equipment that can use DOCSIS data. In some embodiments, the cable modem 76 is omitted and in other embodiments, the graphics generator 62 is omitted.

The circuitry in FIG. 2, or the previously identified subsets of the various embodiments described herein, is typically placed on a “daughter board” printed circuit board (PCB) which is mounted physically to the “mother board” PCB of the analog set top box which contains the circuitry of FIG. 1. Typically, this daughter board is mounted to the motherboard at the location of the microprocessor 34 and flash and DRAM chips 35 and 37 which are typically removed from the motherboard. The daughter board has connection pads thereon. The points in the circuitry marked with X in a circle on the block diagram of FIG. 1 are the typical places where the circuitry of FIG. 2 connects to the circuitry to be re-used from the circuit of FIG. 1. The circuit board traces at these Xs is broken and one or more wires as needed are soldered from the point of the break (on the appropriate side of the break) to the appropriate connection pad on the daughter board to make the circuit.

The daughter board can be a conventional PCB with integrated circuits that perform all the functions of FIG. 2 mounted thereon and interconnected suitably by PCB traces to form the circuit of FIG. 2 or any of the embodiments described above. The appropriate inputs and outputs of the circuit of FIG. 2 (or any of the alternative embodiments) are then coupled to connection pads on the daughter board, and the connection pads are connected in any way to the appropriate sides of the circuit breaks marked by Xs in FIG. 2. Typically, this will be done by soldering wires from the connection points on the daughter board to the circuit breaks.

In alternative embodiments, the daughter board can be constructed using a multichip module (MCM). An MCM is comprised of a substrate or support of a single integrated circuit package on which is mounted the individual integrated circuit dies of all the circuits (or the appropriate subset thereof depending upon the embodiment) of FIG. 2. These die are mechanically supported by an adhesive on the substrate and appropriate connections between them are wire bonded. The resulting circuit is then encased in a protective epoxy or other coating and the resulting MCM (which looks like an integrated circuit with a single die therein) is mounted on the daughter board in a conventional way. The pins of the MCM are then coupled to connection pads by conductive traces on the daughterboard PCB, and those connection pads are coupled to the appropriate break points on the circuit of FIG. 1.

In embodiments where the amount of circuitry is too much to fit onto a single MCM substrate, two or more MCM packages can be used and suitably connected by conductive traces on the daughter board. The appropriate pins of the MCM packages are then coupled to connection pads on the daughter board and to appropriate break points in the circuit of FIG. 1 to complete the digital set top box conversion.

FIG. 3 is a drawing of a typical mounting of a daughter board on a mother board. PCB 82 is the daughter board and has integrated circuits mounted thereon of which ICs 84 and 86 are typical. ICs 84 and 86 also represent one or more MCMs in MCM embodiments. Conductive trace, not shown, on the daughter board couple the ICs together and to connection pads at 88 and 90. Wires 92 and 94 are typical of the plurality of wires that couple the connection pads on the daughter board to circuit breaks on the mother board 97 of which circuit breaks at 96 and 98 are typical.

The advantage of re-furbishing analog set top decoder boxes as described herein is that the following parts can be re-used to leverage the costs of production substantially downward: the enclosure; the power supply and regulator circuitry;

the front panel switches, if any; the LEDs; the display; possibly the flash and DRAM memories; the infrared receiver; the tuner; the analog SAW fitler and the remodulation circuit. Re-use of these parts can substantially reduce the cost of manufacture of digital cable compatible set top boxes.

Although the invention has been disclosed in terms of the preferred and alternative embodiments disclosed herein, those skilled in the art will appreciate possible alternative embodiments and other modifications to the teachings disclosed herein which do not depart from the spirit and scope of the invention. All such alternative embodiments and other modifications are intended to be included within the scope of the claims appended hereto.

What is claimed is:

1. A process for refurbishing an analog set top decoder box that is not capable of tuning to different channels of a digital cable television system (hereafter the target set top box) so that said target set top box is transformed into a digital set top box which is capable of tuning to any channel of a digital cable television system, comprising the steps of:
1) mounting on a printed circuit board all the needed circuitry of a replacement circuit, said replacement circuit including all integrated circuits needed to perform functions of a digital set top box which is capable of tuning to any channel of a digital cable television system and converting the digital data delivered on said channel to a video signal;
2) breaking connections on a printed circuit board of said target set top box (hereafter the motherboard) at predetermined points and making suitable connections between said replacement circuitry created in step 1 to the appropriate sides of said break points on said motherboard so as to re-use circuitry and apparatus of said target set top box (hereafter referred to as re-used apparatus) with said replacement circuit so as to create a digital set top tuner/decoder which is capable of tuning to any channel of a digital cable system and converting the digital data received on said channel to a video signal modulated onto a radio frequency carrier of a predetermined frequency or a video signal output at baseband outputs, or both.

2. The process of claim 1 wherein step 1 comprises creating a replacement printed circuit board with said replacement circuit formed thereon, and mounting said replacement printed circuit board on said motherboard of said target set top box, and wherein the step of creating said replacement circuit comprises mounting on said replacement printed circuit board integrated circuits implementing a microprocessor, a digital demodulator, a flash memory of a suitable size for digital set top box applications if necessary because the flash memory of the target set top box is too small, a DRAM of a suitable size for digital set top box applications if necessary because the DRAM of the target set top box is too small, an MPEG transport stream demultiplexer, and an MPEG decoder, and forming conductive traces on said replacement printed circuit board to connect said integrated circuits together suitably to form a circuit which has connection points which when suitably connected to appropriate predetermined points on said motherboard of said target set top box, re-uses predetermined components of said analog set top box and forms a digital set top tuner/decoder capable of tuning to any channel on a digital cable system.

3. The process of claim 2 wherein said step of creating said replacement circuit further comprises the steps of mounting the integrated circuits of a DOCSIS compatible cable modem on said replacement circuit board and mounting a local area network connector on an enclosure of said target set top box and forming conductive traces on said replacement circuit board which are such as to connect the integrated circuits of said DOCSIS compatible cable modem together to form a DOCSIS compatible cable modem, and wherein said step of making suitable connections between said replacement circuitry created in step 1 to points in the circuitry of said motherboard further comprises the step of making a coaxial cable connection between a coaxial cable input of said DOCSIS compatible cable modem and the coaxial cable input on an enclosure for said target set top box which is present to allow said target set top box to be coupled to the coaxial cable of a hybrid fiber coaxial cable digital cable system, and further comprises making suitable connections between a local area network output of said DOCSIS compatible cable modem and said local area network connector mounted on said enclosure of said target set top box.

4. The process of claim 2 wherein said step of creating said replacement circuit further comprises the steps of mounting the integrated circuit(s) of a graphics generator on said replacement circuit board and forming conductive traces on said replacement circuit board such that said graphics generator is coupled to said MPEG transport stream demultiplexer so as to receive auxiliary data to be converted to video signals that provide on screen information about programs to be viewed by a user to gain information about one or more programs, and wherein the step of making suitable connections between said replacement circuitry created in step 1 to the appropriate sides of said break points on said motherboard further comprises the steps of making suitable connections between connection pads on said replacement circuit board coupled to the output of said graphics generator to an input of a re-modulator circuit on said motherboard of said target set top box such that video signals embodying said on-screen graphics generated by said graphics generator will be superimposed on the screen of a television set coupled to an output of said digital set top tuner/decoder.

5. The process of claim 1 wherein step 1 comprises creating a replacement printed circuit board with a suitable replacement circuit thereon, and mounting said replacement printed circuit board on said printed circuit board of said target modem, and wherein the step of creating said replacement printed circuit board comprises mounting a multichip module having mounted on a substrate thereof a plurality of integrated circuit die which implement a microprocessor, a digital demodulator, a flash memory of a suitable size for digital set top box applications if necessary because the flash memory of the target set top box is too small, a DRAM of a suitable size for digital set top box applications if necessary because the DRAM of the target set top box is too small, an MPEG transport stream demultiplexer, and an MPEG decoder and making wire bond connections between said integrated circuit die which are suitable to form said replacement circuit.

6. The process of claim 5 wherein step 1 further comprises mounting on said substrate of said multichip module one or more integrated circuit die which implement a DOCSIS compatible cable modem and forming wire bonds to connect said DOCSIS compatible cable modem to a plurality of pins of said multichip module which are connected to connection pads, and wherein the step of making suitable connections between said replacement circuitry created in step 1 to the circuitry on said motherboard includes making a coaxial cable connection between said replacement circuit board connection pads coupled to an RF input of said DOCSIS compatible cable modem and an RF input of said digital set top tuner/decoder.

7. The process of claim 5 wherein step 1 further comprises mounting on said substrate of said multichip module one or more integrated circuit die which implement a graphics generator and forming wire bonds to connect said graphics generator to said integrated circuit die which implement said MPEG transport stream demultiplexer such that said graphic generator will receive digital auxiliary data culled from the downstream MPEG transport stream(s) which encode information about one or more programs encoded in the data of the MPEG transport stream, and making suitable wire bonds to connect the output of said graphics generator circuit to pins of said multichip module, and wherein the step of making suitable connections between said replacement circuitry created in step to the circuitry on said motherboard includes making connections between said pins of said multichip module connected to said output of said graphics generator and a circuit break at the input of a remodulator circuit on said motherboard which is to be re-used such that video signals encoding on screen graphics displaying information about one or more programs is output by said remodulator for display on a television.

8. The process of claim 1 wherein the step of creating said replacement circuit accomplished in step 1 comprises mounting all the integrated circuits needed to implement said digital set top tuner/decoder on the motherboard of said target set top box in the locations where integrated circuits of said target set top box which are no longer needed and have been removed, and making suitable connections between said integrated circuits of said replacement circuit to form said replacement circuit and forming interconnection pads on said motherboard of said target set top box, and wherein step 2 includes making electrical connection between said interconnection pads of said replacement circuit formed on said motherboard to the appropriate sides of said break points in the circuitry of said motherboard to form a digital set top tuner/decoder which re-uses some of the components of said target set top box to implement a digital set top tuner/decoder.

9. A process for refurbishing analog set top tuner/decoders (hereafter target set top tuner/decoders) so as to re-use certain components of said target set top tuner/decoders and convert said target set top tuner/decoders into digital set top tuner/decoders capable of tuning any channel on a digital cable TV system, comprising the steps:
1) removing a control microprocessor integrated circuit and selected other integrated circuits that are not needed to make space to mount a replacement circuit;
2) physically mounting a replacement printed circuit board at the location where said integrated circuits were removed in step 1, said replacement printed circuit board having mounted thereon and suitably connected all circuitry thereon which is necessary to perform the functions necessary to re-use predetermined components of said target set top tuner/decoder and convert it to a digital set top tuner/decoder;
3) breaking connections on a printed circuit board of said target set top tuner/decoder at all points necessary to supply signals to circuits on said replacement printed circuit board and to supply signals from circuits on said replacement printed circuit board to circuits or apparatus on said printed circuit board of said target set top tuner/decoder so as to cause said circuits on said replacement printed circuit board to and supply signals to the appropriate places on said printed circuit board of said so as to re-use circuits and apparatus on said printed circuit board of said target set top tuner/decoder to form a digital set top tuner/decoder;
4) making electrical connections in any way between the predetermined points of circuitry on said replacement printed circuit board and appropriate points on said printed circuit board of said target set top tuner/decoder so as to complete the circuitry of a functional digital set top tuner/decoder.

10. A digital set top tuner/decoder made from an analog set top tuner/decoder, comprising:
a printed circuit board of said analog set top tuner/decoder (hereafter referred to as the motherboard), said printed circuit board including circuits to be re-used including an infrared receiver, a voltage regulator, a tuner, an analog SAW fitler, and a remodulation circuit as well as various discrete components such as resistors, capacitors and possibly inductors, and including circuitry that is not to be re-used;
an enclosure having LEDs, possibly front panel switches, a window for receiving infrared commands, an RF input connector and an RF output connector, and a DC input connector to receive DC power to power circuitry on said motherboard all of which were present in said analog set top tuner/decoder and which are to be re-used;
a power supply and cables to connect said power supply to a wall power outlet and to said DC power input connector on said enclosure, all of which were present in said analog set top tuner/decoder and which are to be re-used
conductors to connect circuitry on said motherboard to said LEDs, said front panel switches if any, and said RF input connector and said RF output connector and said DC power input; and
a replacement circuit board having circuitry formed thereon which performs functions which, when suitably connected to said circuitry and components on said motherboard and said enclosure to be re-used will convert said analog set top tuner/decoder into a digital set top tuner/decoder, said replacement circuit board physically mounted to said motherboard and electrically connected to predetermined points of circuitry on said motherboard so as to create a digital set top tuner/decoder which re-uses circuitry and apparatus from said analog set top decoder thereby greatly saving on the expense of building a digital set top tuner/decoder.
